(19) United States
(12) Patent Application Publication
(10) Pub. No.: US 2025/0379074 A1
(43) Pub. Date: Dec. 11, 2025

(54) APPARATUS AND METHOD FOR DISPENSING FLUID MATERIAL, AND COOLING DEVICE

(71) Applicant: STATS ChipPAC Pte. Ltd., Singapore (SG)

(72) Inventors: JungHo KIM, Incheon (KR); JoungJai YOO, Incheon (KR); MoonSu HAN, Incheon (KR)

(21) Appl. No.: 19/220,130

(22) Filed: May 28, 2025

(30) Foreign Application Priority Data
Jun. 11, 2024 (CN) 202410748201.3

(51) Int. Cl. H01L 21/67

(52) U.S. Cl. CPC H01L 21/6715; H01L 21/67248

(57) ABSTRACT

An apparatus and a method for dispensing a fluid material, and a cooling device are provided. The apparatus may include: a syringe container configured for accommodating a fluid material; and a dispensing pump in fluid communication with the syringe container and configured for dispensing the fluid material on an object; and a cooling device including: a coolant source configured for generating a coolant flow; and a cooling body in fluid communication with the coolant source and configured for directing the coolant flow to the syringe container to cool the fluid material therein.

### TECHNICAL FIELD

The present application generally relates to semiconductor technology, and more particularly, to an apparatus and a method for dispensing a fluid material, and a cooling device.

### BACKGROUND OF THE INVENTION

The semiconductor industry is constantly faced with complex integration challenges as consumers want their electronics to be smaller, faster and higher performance with more and more functionalities packed into a single device. In the manufacture of semiconductor devices, various dispensing apparatuses may be used to dispense different fluid materials, such as solder paste, adhesives, thermal compounds, and encapsulants. However, viscosities of the fluid materials may increase during the dispensing process, causing them to harden and be difficult to be dispensed from the dispensing apparatuses.

Therefore, a need exists for an apparatus for smoothly dispensing a fluid material.

### SUMMARY OF THE INVENTION

An objective of the present application is to provide an apparatus for smoothly dispensing a fluid material.

According to an aspect of the present application, an apparatus for dispensing a fluid material is provided. The apparatus may include: a syringe container configured for accommodating a fluid material; and a dispensing pump in fluid communication with the syringe container and configured for dispensing the fluid material on an object; and a cooling device including: a coolant source configured for generating a coolant flow; and a cooling body in fluid communication with the coolant source and configured for directing the coolant flow to the syringe container to cool the fluid material therein.

According to another aspect of the present application, a cooling device for cooling a fluid material in a container is provided. The cooling device may include: a coolant source configured for generating a coolant flow; and a cooling body in fluid communication with the coolant source and configured for directing the coolant flow to the container to cool the fluid material therein.

According to still another aspect of the present application, A method for dispensing a fluid material is provided. The method may include: generating, by a coolant source, a coolant flow; directing, by a cooling body in fluid communication with the coolant source, the coolant flow to a syringe container to cool the fluid material accommodated therein; and dispensing, by a dispensing pump in fluid communication with the syringe container, the fluid material on an object.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1 is a perspective view illustrating an apparatus for dispensing a fluid material on a semiconductor device.

FIG. 2 is a perspective view illustrating an apparatus for dispensing a fluid material according to an embodiment of the present application.

FIG. 3A is a perspective view illustrating a coolant source according to an embodiment of the present application.

FIG. 3B is a schematic diagram of a coolant source according to an embodiment of the present application.

FIG. 4A is a cross-sectional view illustrating an apparatus for dispensing a fluid material according to an embodiment of the present application.

FIG. 4B is a cross-sectional view illustrating a cooling body according to an embodiment of the present application.

FIG. 4C is a perspective view illustrating a syringe container according to an embodiment of the present application.

FIG. 5 is a flowchart illustrating a method for dispensing a fluid material according to an embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

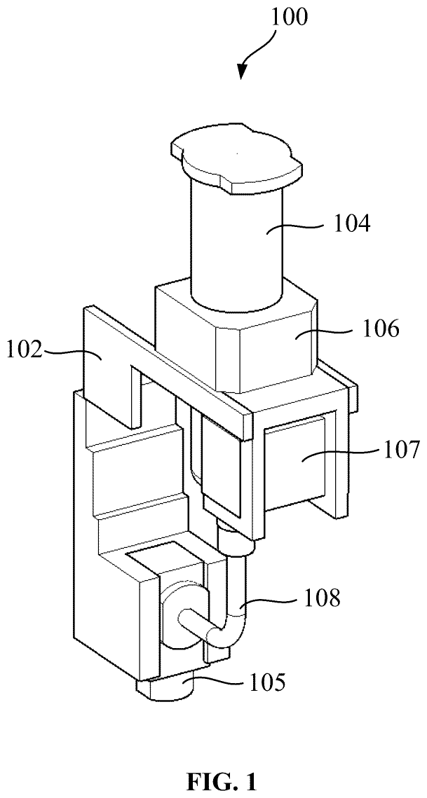

Referring to FIG. 1, a perspective view of an apparatus 100 for dispensing a fluid material on a semiconductor device is illustrated.

The apparatus 100 may include a syringe container 104 and a dispensing pump 105 mounted on a main body 102. The syringe container 104 may have a substantially cylindrical body for accommodating a fluid material, and be mounted on the main body 102 via a syringe holder 106. As shown in FIG. 1, the syringe container 104 includes an upper end portion and a lower end portion, and the lower end portion of the syringe container 104 may be in fluid communication with the dispensing pump 105 through a hose or tube 108. The dispensing pump 105 may be configured for dispensing the fluid material on an object, for example, on a semiconductor device. The apparatus 100 may include a sensor 107 mounted on the syringe container 104 to detect an amount of fluid material in the syringe container 104, for example, to determine whether the fluid material in the syringe container 104 has run out. The apparatus 100 may further include a controller configured to control the operation of the syringe container 104 and the dispensing pump 105.

In an example, the apparatus 100 may be used to dispense epoxy resin adhesive. During the dispensing process, the apparatus 100 may be exposed to many heat dissipation devices, causing a temperature of the epoxy resin adhesive to rise. A viscosity of the epoxy resin adhesive may increase when its temperature rises, and thus the epoxy resin adhesive may be difficult to be dispensed from the dispensing apparatus.

To address the above problem, an apparatus for dispensing a fluid material is provided in some embodiments of the present application. In the apparatus, a cooling device is introduced into the dispensing apparatus to cool the fluid material or maintain the fluid material at a proper temperature. Thus, the fluid material can be dispensed from apparatus smoothly.

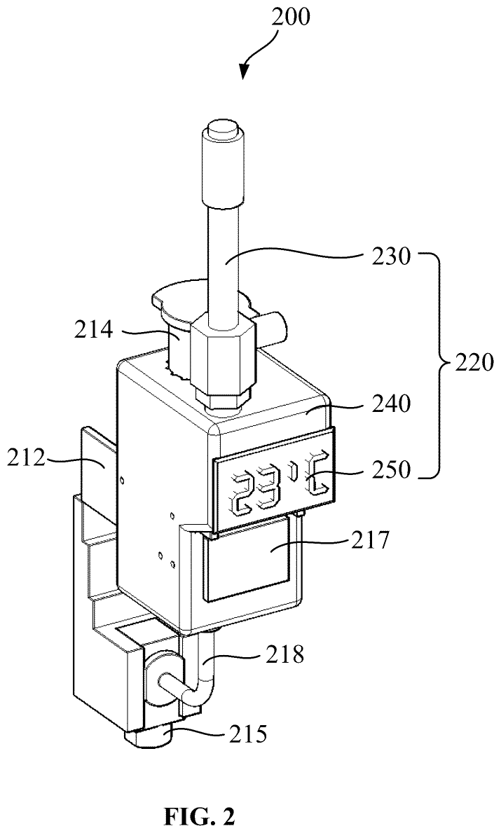

Referring to FIG. 2, a perspective view of an apparatus 200 for dispensing a fluid material is illustrated according to an embodiment of the present application.

As shown in FIG. 2, the apparatus 200 may include a syringe container 214 and a dispensing pump 215 mounted on a main body 212. The syringe container 214 is configured for accommodating a fluid material, and the dispensing pump 215 is in fluid communication with the syringe container 214 and configured for dispensing the fluid material on an object, for example, on a semiconductor device. The syringe container 214 may be in fluid communication with the dispensing pump 215 through a hose or tube 218. The apparatus 200 may include a sensor 217 mounted on the syringe container 214 to detect an amount of fluid material in the syringe container 214, for example, to determine whether the fluid material in the syringe container 214 has run out.

In some embodiments, the apparatus 200 may be used to dispense epoxy resin adhesive, that is, the fluid material accommodated in the syringe container 214 may be epoxy resin adhesive. In an example, in order to smoothly dispense the epoxy resin adhesive from the apparatus 200, a temperature of the epoxy resin adhesive in the syringe container 214 should be maintain at 23±0.2° C. However, the present application is not limited thereto. In some other embodiments, the apparatus 200 may be used to dispense other fluid materials, such as encapsulants, solder fluxes, solder pastes, thermal compounds, oils, inks, silicones, and any fluid material that may need to be maintained at a proper temperature, for example, at a temperature which can maintain its viscosity at a proper range.

The apparatus 200 shown in FIG. 2 may have similar structures and configurations as the apparatus 100 shown in FIG. 1. The similar or same parts between the apparatus 200 and the apparatus 100 will not be repeated herein. Different from the apparatus 100 shown in FIG. 1, the apparatus 200 shown in FIG. 2 further includes a cooling device 220 to cool the fluid material in the syringe container 214 or maintain the fluid material at a proper temperature. As shown in FIG. 2, the cooling device 220 may include a coolant source 230 and a cooling body 240. The coolant source 230 is configured for generating a coolant flow, and the cooling body 240 is in fluid communication with the coolant source 230 and is configured for directing the coolant flow to the syringe container 214 to cool the fluid material therein.

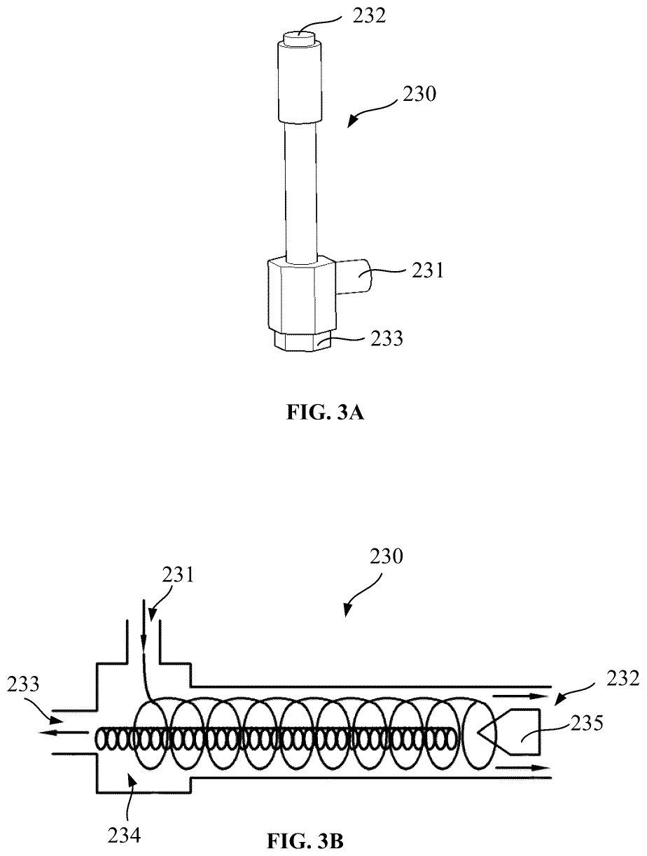

Referring to FIG. 3A and FIG. 3B, a perspective view and a schematic diagram of the coolant source 230 are illustrated according to an embodiment of the present application. The coolant source 230 may be a vortex tube, and the coolant flow is a flow of cooling air generated by the vortex tube.

As shown in FIG. 3A and FIG. 3B, the vortex tube includes an inlet 231, a first outlet 232 and a second outlet 233, which intersect with each other at a vortex spin chamber 234. When the vortex tube is supplied with a compressed air flow (for example, normally 80 to 100 PSIG (5.5 to 6.9 Bar)) through the inlet 231, the air flow is directed into the vortex spin chamber 234 to generate a spiraling vortex at around 1,000,000 rpm. The spiraling vortex may flow to the first outlet 232 where a control valve 235 is disposed. The control valve 235 allows a fraction of air to escape from the first outlet 232, while maintaining the other portion within the tube. The remaining air that does not escape may still spin, flow in a reverse direction and travel back to the second outlet 233.

As shown in FIG. 3B, an inner stream (i.e., the remaining air traveling back to the second outlet 233) of the air flow can give off kinetic energy in the form of heat to the outer stream (i.e., the fraction of the air escaping from the first outlet 232). Thus, the outer stream exits the vortex tube from the first outlet 232 as a hot air flow, and the inner stream exits the vortex tube from the second outlet 233 as a cold air flow. In other words, the vortex tube can separate a compressed air into two air flows, i.e., a hot air flow and a cold air flow. Depending on a shape of the vortex tube and an amount of input compressed air, a temperature of the hot air flow can rise to, for example, 200° C., and a temperature of the cold air flow can drop to, for example, −50° C. The temperature of the cold air flow can be easily adjustable by adjusting an amount of compressed air input into the vortex tube. As the vortex tube does not have any movable part, the coolant source 230 is reliable and inexpensive, and requires no electrical components to generate the coolant flow.

In the above embodiment, the coolant source 230 is a vortex tube, and the coolant flow is a flow of cooling air. However, the present application is not limited thereto. In some other embodiments, the coolant source 230 may have other structures and configurations, and the coolant flow may be a liquid flow.

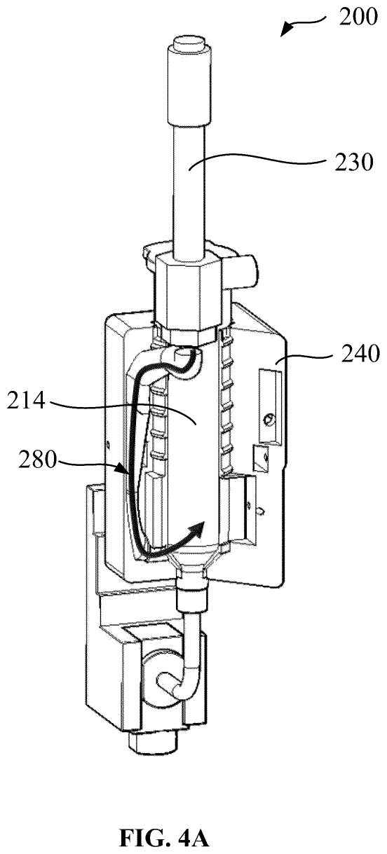

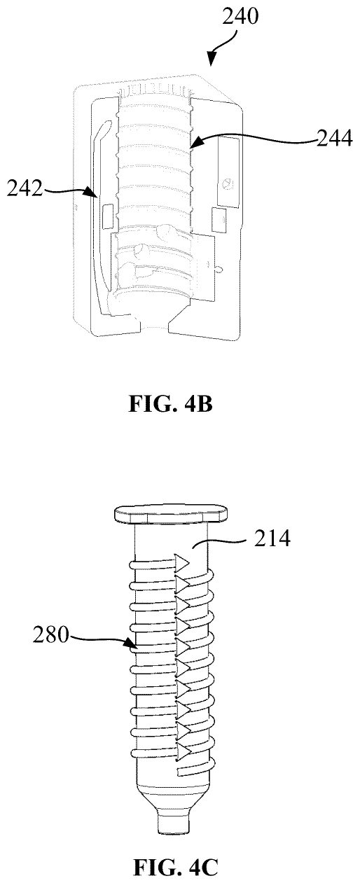

FIGS. 4A, 4B and 4C show another example of the apparatus 200 for dispensing a fluid material according to an embodiment of the present application. In particular, a cross-sectional view of the apparatus 200 is illustrated in FIG. 4A, a cross-sectional view of the cooling body 240 is illustrated in FIG. 4B, and a perspective view of the syringe container 214 is illustrated in FIG. 4C.

The cooling body 240 may surround at least a portion of the syringe container 214. For example, as shown in FIGS. 4A and 4B, the cooling body 240 may have a rectangular shape or a cylindrical shape. The cooling body 240 has a through hole extending in a height direction or vertically, and the syringe container 214 is disposed in the through hole.

Referring to FIG. 4A and FIG. 4B, the cooling body 240 includes a first passageway 242 and a second passageway 244. The first passageway 242 is formed inside the cooling body 240 and extends in a height direction of the cooling body 240.

An upper end of the first passageway 242 may be fluidly coupled with the coolant source 230 to receive a coolant flow 280 and then direct the coolant flow 280 to flow downwards to a lower portion of the cooling body 240. The second passageway 244 is formed on an inner surface of the cooling body 240 and adjacent to the syringe container 214. The second passageway 244 is in fluid communication with the first passageway 242 at the lower portion of the cooling body 242 via a lower end of the first passageway 242. The second passageway 244 is configured to direct the coolant flow 280 to flow upwards in the second passageway 244 and along an outer surface of the syringe container 241.

In some embodiments, the second passageway 244 is a spiral groove formed on the inner surface of the cooling body 240. As shown in FIG. 4C, the spiral groove can increase the contact area between the coolant flow 280 and the syringe container 214, thereby improving the cooling efficiency. It can be appreciated that the second passageway 244 may have other shapes such as a grid shape. It could be understood that the cooling body 240 shown in FIG. 4A and FIG. 4B are only exemplary and the present application is not limited thereto. In some other embodiments, the cooling body 240 may have other structures and configurations.

Referring back to FIG. 2, the cooling device 220 may further include a temperature sensor (not shown) and a display unit 250. The temperature sensor may be mounted on the syringe container 214 and configured to detect a temperature of the fluid material accommodated in the syringe container 214. The display unit 250 is configured to obtain the temperature of the fluid material from the temperature sensor directly, or indirectly via a controller, and display the temperature of the fluid material. In this way, an operator of the apparatus 200 can know the status, or particularly the temperature, of the fluid material. Thus, the operator can adjust a temperature of the cooling air, for example, by adjusting an amount of compressed air input into the vortex tube shown in FIG. 3A and FIG. 3B, so as to maintain the fluid material at a proper temperature. In some other examples, an automatic adjustment mechanism or algorithm can be used to adjust the amount of compressed air into the vortex tube and thus the temperature of the fluid material, for example, depending on the type of fluid material to be dispensed. It could be understood that the above embodiment is only exemplary and the present application is not limited thereto. In some other embodiments, the cooling device 220 may include a viscosity sensor to detect a viscosity of the fluid material accommodated in the syringe container 214, or a pressure sensor to determine whether the fluid substances have solidified, so as to determine whether the fluid material is within an appropriate temperature range.

In some embodiments, the apparatus 200 may further include a controller (not shown) configured to control the operation of the syringe container 214, the dispensing pump 215 and the cooling device 220. For example, the controller may be electrically coupled with the temperature sensor and the coolant source 230, such that the controller can adjust a temperature of the coolant flow (for example, by adjusting an amount of compressed air input into the vortex tube shown in FIG. 3A) in response to a temperature signal received from the temperature sensor. The controller can automatically control the temperature of the fluid material using temperature information from the temperature sensor without manual intervention.

In some embodiments, the apparatus 200 may further include a heating device (not shown) configured for heating the fluid material accommodated in the syringe container 214. Thus, the controller may be configured to control the cooling device 220 to cool the fluid material accommodated in the syringe container 214 when its temperature is higher than a predetermined temperature, and to control the heating device to heat the fluid material accommodated in the syringe container 214 when its temperature is lower than the predetermined temperature, making it easier to maintain the temperature of the fluid material at the predetermined temperature. In some embodiments, the heating device may include an electric resistance heater surrounding an exterior of the syringe container 214. In some embodiments, the heating device may receive the hot air flow from the first outlet 232 of the vortex tube to heat the fluid material accommodated in the syringe container 214. For example, the controller can control the heating device and the cooling device to allow the hot air flow from the first outlet 232, the cold air flow from the second outlet 233, or a mixture of the hot air flow and the cold air flow to enter the cooling body 240. The controller can adjust the temperature of the fluid material accommodated in the syringe container 214 by adjusting a proportion of the hot air flow and the cold air flow entering the cooling body 240.

In an experiment employing the dispensing apparatus according to an embodiment of the present application, although an external environmental temperature of the apparatus 200 varies significantly around 26° C., the temperature of epoxy resin adhesive accommodated in the syringe container 214 of the apparatus 200 can be maintained precisely at 23° C., ensuring smooth dispensing of the epoxy resin adhesive from the apparatus 200.

According to another aspect of the present application, a method for dispensing a fluid material is provided. The method may be, for example, implemented by the dispensing apparatus shown in FIG. 2.

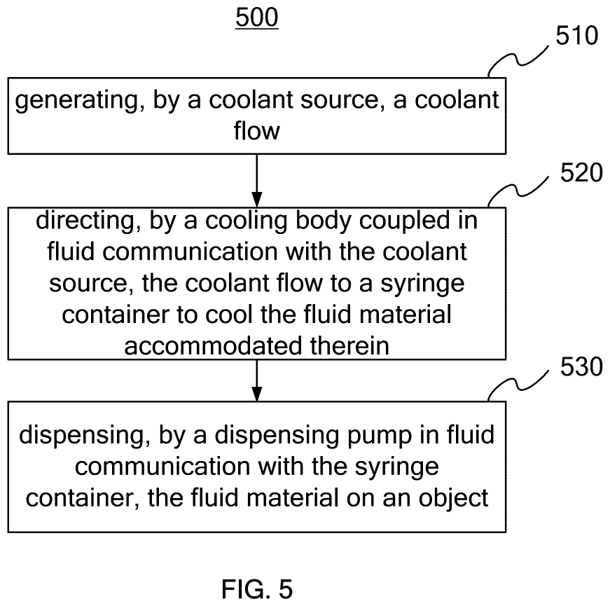

Referring to FIG. 5, a flowchart illustrating a method 500 for dispensing a fluid material is illustrated according to an embodiment of the present application. As illustrated in FIG. 5, the method 500 may start with generating, by a coolant source such as the coolant source 230 shown in FIG. 2, FIG. 3A and FIG. 3B, a coolant flow in block 510. Then, in block 520, a cooling body in fluid communication with the coolant source may be used to direct the coolant flow to a syringe container accommodating the fluid material. For example, the cooling body 240 shown in FIG. 2, FIG. 4A and FIG. 4B may be used to direct the coolant flow to the syringe container 214 shown in FIG. 2, FIG. 4A and FIG. 4C to cool the fluid material accommodated therein. Afterwards, in block 530, a dispensing pump in fluid communication with the syringe container may be used to dispense the fluid material on an object. For example, the dispensing pump shown in FIG. 2 may be used to dispense the fluid material on the object.

In some embodiments, the coolant source may include a vortex tube, the coolant flow is a flow of cooling air generated by the vortex tube, and the method 500 may include: adjusting a temperature of the cooling air by adjusting an amount of compressed air input into the vortex tube. In some embodiments, the fluid material may include epoxy resin adhesive.

More details about the method may refer to the apparatuses and device described in the above embodiments, and will not be elaborated herein.

The discussion herein included numerous illustrative figures that showed various portions of an apparatus and a method for dispensing a fluid material, and a cooling device. For illustrative clarity, such figures did not show all aspects of each example device. Any of the example apparatus and/or methods provided herein may share any or all characteristics with any or all other apparatus and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. An apparatus for dispensing a fluid material, comprising:
a syringe container configured for accommodating a fluid material; and
a dispensing pump in fluid communication with the syringe container and configured for dispensing the fluid material on an object; and
a cooling device comprising:
a coolant source configured for generating a coolant flow; and
a cooling body in fluid communication with the coolant source and configured for directing the coolant flow to the syringe container to cool the fluid material therein.

2. The apparatus of claim 1, wherein the coolant source comprises a vortex tube, and the coolant flow is a flow of cooling air generated by the vortex tube.

3. The apparatus of claim 2, wherein the vortex tube is configured to adjust a temperature of the cooling air by adjusting an amount of compressed air input into the vortex tube.

4. The apparatus of claim 1, wherein the cooling body surrounds at least a portion of the syringe container, and comprises:
a first passageway formed inside the cooling body and extending in a height direction of the cooling body to direct the coolant flow to flow downwards from the coolant source to a lower portion of the cooling body; and
a second passageway formed on an inner surface of the cooling body and adjacent to the syringe container, wherein the second passageway is in fluid communication with the first passageway at the lower portion of the cooling body, and is configured to direct the coolant flow to flow upwards in the second passageway and along an outer surface of the syringe container.

5. The apparatus of claim 4, wherein the second passageway is a spiral groove formed on the inner surface of the cooling body.

6. The apparatus of claim 1, wherein the cooling device further comprises a temperature sensor, and the temperature sensor is mounted on the syringe container and configured to detect a temperature of the fluid material accommodated in the syringe container.

7. The apparatus of claim 6, wherein the cooling device further comprises a display unit, and the display unit is configured to obtain the temperature of the fluid material from the temperature sensor and display the temperature of the fluid material to an operator.

8. The apparatus of claim 1, further comprising:
a heating device configured for heating the fluid material accommodated in the syringe container.

9. The apparatus of claim 1, wherein the fluid material comprises epoxy resin adhesive.

10. A cooling device for cooling a fluid material in a container, comprising:
a coolant source configured for generating a coolant flow; and
a cooling body in fluid communication with the coolant source and configured for directing the coolant flow to the container to cool the fluid material therein.

11. The cooling device of claim 10, wherein the coolant source comprises a vortex tube, and the coolant flow is a flow of cooling air generated by the vortex tube.

12. The cooling device of claim 11, wherein the vortex tube is configured to adjust a temperature of the cooling air by adjusting an amount of compressed air input into the vortex tube.

13. The cooling device of claim 10, wherein the cooling body surrounds at least a portion of the container, and comprises:
a first passageway formed inside the cooling body and extending in a height direction of the cooling body to direct the coolant flow to flow downwards from the coolant source to a lower portion of the cooling body; and
a second passageway formed on an inner surface of the cooling body and adjacent to the container, wherein the second passageway is in fluid communication with the first passageway at the lower portion of the cooling body, and is configured to direct the coolant flow to flow upwards in the second passageway and along an outer surface of the container.

14. The cooling device of claim 13, wherein the second passageway is a spiral groove formed on the inner surface of the cooling body.

15. The cooling device of claim 10, further comprising:
a temperature sensor, wherein the temperature sensor is mounted on the container and configured to detect a temperature of the fluid material accommodated in the container.

16. The cooling device of claim 15, further comprising:
a display unit, wherein the display unit is configured to obtain the temperature of the fluid material from the temperature sensor and display the temperature of the fluid material to an operator.

17. A method for dispensing a fluid material, comprising:
generating, by a coolant source, a coolant flow;
directing, by a cooling body in fluid communication with the coolant source, the coolant flow to a syringe container to cool the fluid material accommodated therein; and
dispensing, by a dispensing pump in fluid communication with the syringe container, the fluid material on an object.

18. The method of claim 17, wherein the coolant source comprises a vortex tube, the coolant flow is a flow of cooling air generated by the vortex tube, and the method further comprises:
adjusting a temperature of the cooling air by adjusting an amount of compressed air input into the vortex tube.

19. The method of claim 17, wherein the fluid material comprises epoxy resin adhesive.
